(19) United States
(12) Patent Application Publication
(10) Pub. No.: US 2025/0225643 A1
(43) Pub. Date: Jul. 10, 2025

(54) INSPECTION ASSISTANCE SYSTEM, INSPECTION ASSISTANCE METHOD, AND INSPECTION ASSISTANCE COMPUTER-READABLE RECORDING MEDIUM STORING PROGRAM

(71) Applicant: MITSUBISHI HEAVY INDUSTRIES, LTD., Tokyo (JP)

(72) Inventors: Shota ISHII, Tokyo (JP); Tatsuya SAKAI, Tokyo (JP); Makoto TANAKA, Tokyo (JP)

(21) Appl. No.: 18/690,076

(22) PCT Filed: Jan. 5, 2023
(86) PCT No.: PCT/JP2023/000032

§ 371 Date: Mar. 7, 2024

(30) Foreign Application Priority Data
Mar. 28, 2022 (JP) 2022-051343

(51) Int. Cl. G06T 7/00; G01N 21/88; G01N 21/95; G06F 30/20; G06T 7/50; G06T 7/80

(52) U.S. Cl. CPC G06T 7/0008; G01N 21/8851; G01N 21/9515; G06F 30/20; G06T 7/50; G06T 7/80; G06T 2207/30108; G06T 2207/30244

(57) ABSTRACT

An inspection assistance system includes an identification shape unit, a defect detection unit, a coordinate transformation parameter estimation unit, a three-dimensional CAD model position change unit, a two-dimensional simulated image extraction unit, and a depiction unit. The identification shape unit recognizes a shape of an inspection target object based on a two-dimensional photographed image captured by an imaging device. The defect detection unit detects a defect of the inspection target object included in the two-dimensional photographed image. Based on the recognized shape and a three-dimensional CAD model, the coordinate transformation parameter estimation unit estimates a coordinate transformation parameter to transform a first coordinate system corresponding to the three-dimensional CAD model into a second coordinate system corresponding to a viewpoint of the imaging device that captured the two-dimensional photographed image. The three-dimensional CAD model position change unit modifies a position and a direction of viewpoint information of the three-dimensional CAD model.

### TECHNICAL FIELD

The present disclosure relates to an inspection assistance system, an inspection assistance method, and an inspection assistance computer-readable recording medium storing a program.

The present application claims priority based on Japanese Patent Application No. 2022-051343 filed in Japan on Mar. 28, 2022, the contents of which are incorporated herein by reference.

### BACKGROUND ART

When an inspector visually inspects an inspection target object (including products, mechanical components, and intermediate products in a manufacturing process), determines a dimension of a defect or the like, and fills out a report, it takes time and effort, and differences in abilities of the inspectors cause a variation in accuracy. As a means for solving such a problem, in recent years, by analyzing a two-dimensional photographed image obtained by capturing an inspection target object with an imaging device such as a camera, a technique capable of determining the dimension of a defect or the like has been proposed.

For example, PTL 1 discloses a method that supports inspection work of determining a dimension of a defect or the like in an inspection target object by analyzing a two-dimensional photographed image obtained by capturing the inspection target object in which a three-dimensional CAD model exists in advance. In this document, a shape of the inspection target object included in the two-dimensional photographed image is recognized, and the defect included in the two-dimensional photographed image is depicted on a three-dimensional CAD model by comparing a reference portion included in the corresponding shape with a reference portion included in a two-dimensional simulated image extracted from the three-dimensional CAD model corresponding to the inspection target object. By depicting the defect on the three-dimensional CAD model in this way, it is possible to determine the dimension of the defect on the three-dimensional CAD model.

### CITATION LIST

### Patent Literature

[PTL 1] Japanese Unexamined Patent Application Publication No. 2021-21669

### SUMMARY OF INVENTION

### Technical Problem

In PTL 1 above, in order to depict a defect on a three-dimensional CAD model, coordinate transformation is performed by comparing a reference portion specified from a shape of an inspection target object included in a two-dimensional photographed image with a reference portion on the three-dimensional CAD model. In order to perform such coordinate transformation with high accuracy, it is necessary to fit a position and a direction of the inspection target object included in the two-dimensional photographed image obtained by the imaging device, to a position and a direction set by the three-dimensional CAD model, resulting a low degree of freedom. When the position and the direction of the inspection target object included in the two-dimensional photographed image are significantly different from the position and the direction set in the three-dimensional CAD model, the position of the defect depicted in the three-dimensional CAD model deviates, and determination accuracy of dimensions or the like is reduced.

At least one embodiment of the present disclosure has been made in view of the above circumstances, and an object of the present disclosure is to provide an inspection assistance system, an inspection assistance method, and an inspection assistance computer-readable recording medium storing a program capable of supporting an implementation of an inspection capable of deriving a three-dimensional position and dimension of a defect in an inspection target object via a simple operation.

### Solution to Problem

In order to solve the above problems, an inspection assistance system according to at least one embodiment of the present disclosure includes
a identification shape unit to recognize a shape of an inspection target object included in a two-dimensional photographed image based on the two-dimensional photographed image obtained by capturing the inspection target object with an imaging device,
a defect detection unit to detect a defect of the inspection target object included in the two-dimensional photographed image,
a coordinate transformation parameter estimation unit to estimate a coordinate transformation parameter to transform a first coordinate system corresponding to the three-dimensional CAD model into a second coordinate system corresponding to a viewpoint of the imaging device that has captured the two-dimensional photographed image, based on the shape recognized by the identification shape unit and on a three-dimensional CAD model of the inspection target object,
a three-dimensional CAD model position change unit to modify a position and a direction of viewpoint information of the three-dimensional CAD model of the inspection target object by using the coordinate transformation parameter,
a two-dimensional simulated image extraction unit to extract a two-dimensional simulated image corresponding to the two-dimensional photographed image from the three-dimensional CAD model after the viewpoint information is modified, and
a depiction unit to depict a defect image on the three-dimensional CAD model by fitting the two-dimensional photographed image including the defect image illustrating the defect detected by the defect detection unit to the two-dimensional simulated image.

In order to solve the above problems, an inspection assistance method according to at least one embodiment of the present disclosure includes
a step of recognizing a shape of an inspection target object included in a two-dimensional photographed image based on the two-dimensional photographed image obtained by capturing the inspection target object with an imaging device,
a step of detecting a defect of the inspection target object included in the two-dimensional photographed image,
a step of estimating a coordinate transformation parameter to transform a first coordinate system corresponding to the three-dimensional CAD model into a second coordinate system corresponding to a viewpoint of the imaging device that has captured the two-dimensional photographed image, based on the shape and a three-dimensional CAD model of the inspection target object,
a step of modifying a position and a direction of viewpoint information of the three-dimensional CAD model of the inspection target object by using the coordinate transformation parameter,
a step of extracting a two-dimensional simulated image corresponding to the two-dimensional photographed image from the three-dimensional CAD model after the viewpoint information is modified, and
a step of depicting a defect image on the three-dimensional CAD model by fitting the two-dimensional photographed image including the defect image illustrating the defect to the two-dimensional simulated image.

In order to solve the above problems, an inspection assistance computer-readable recording medium storing a program according to at least one embodiment of the present disclosure causes
a computer to execute
a step of recognizing a shape of an inspection target object included in a two-dimensional photographed image based on the two-dimensional photographed image obtained by capturing the inspection target object with an imaging device,
a step of detecting a defect of the inspection target object included in the two-dimensional photographed image,
a step of estimating a coordinate transformation parameter to transform a first coordinate system corresponding to the three-dimensional CAD model into a second coordinate system corresponding to a viewpoint of the imaging device that has captured the two-dimensional photographed image, based on the shape and a three-dimensional CAD model of the inspection target object,
a step of modifying a position and a direction of viewpoint information of the three-dimensional CAD model of the inspection target object by using the coordinate transformation parameter,
a step of extracting a two-dimensional simulated image corresponding to the two-dimensional photographed image from the three-dimensional CAD model after the viewpoint information is modified, and
a step of depicting a defect image on the three-dimensional CAD model by fitting the two-dimensional photographed image including the defect image illustrating the defect to the two-dimensional simulated image.

### Advantageous Effects of Invention

According to at least one embodiment of the present disclosure, there is provided an inspection assistance system, an inspection assistance method, and an inspection assistance computer-readable recording medium storing a program capable of supporting an implementation of an inspection capable of deriving a three-dimensional position and dimension of a defect in an inspection target object via a simple operation.

### BRIEF DESCRIPTION OF DRAWINGS

FIG. 1 is a block diagram illustrating a schematic configuration of an inspection assistance system according to one embodiment.

FIG. 2 is a schematic diagram illustrating a hardware configuration of a client terminal and a server of FIG. 1.

FIG. 3 is a conceptual diagram for describing a method for detecting a reference portion via a identification shape unit of FIG. 1.

FIG. 4 is a diagram conceptually illustrating a correspondence relationship between a first coordinate system and a second coordinate system based on a coordinate transformation parameter estimated by PNP.

FIG. 5 is a flowchart illustrating an inspection assistance method according to one embodiment.

FIG. 6 is an example of a two-dimensional photographed image captured by an imaging device.

FIG. 7 is a schematic diagram illustrating a default position of a three-dimensional CAD model.

FIG. 8 is a schematic diagram illustrating a posture of the three-dimensional CAD model of FIG. 7 after at least one of a position or direction thereof is modified by a three-dimensional CAD model position change unit.

FIG. 9 is a block diagram illustrating a schematic configuration of an inspection assistance system according to another embodiment.

FIG. 10 is a schematic configuration diagram of a coordinate transformation parameter correction unit of FIG. 9, which is configured as a Variational Autoencoder.

### DESCRIPTION OF EMBODIMENTS

Hereinafter, some embodiments of the present disclosure will be described with reference to the accompanying drawings. However, dimensions, materials, shapes, and relative dispositions of constituent elements described as the embodiments or illustrated in the drawings are not intended to limit the scope of the present disclosure, and are merely examples for describing the present disclosure.

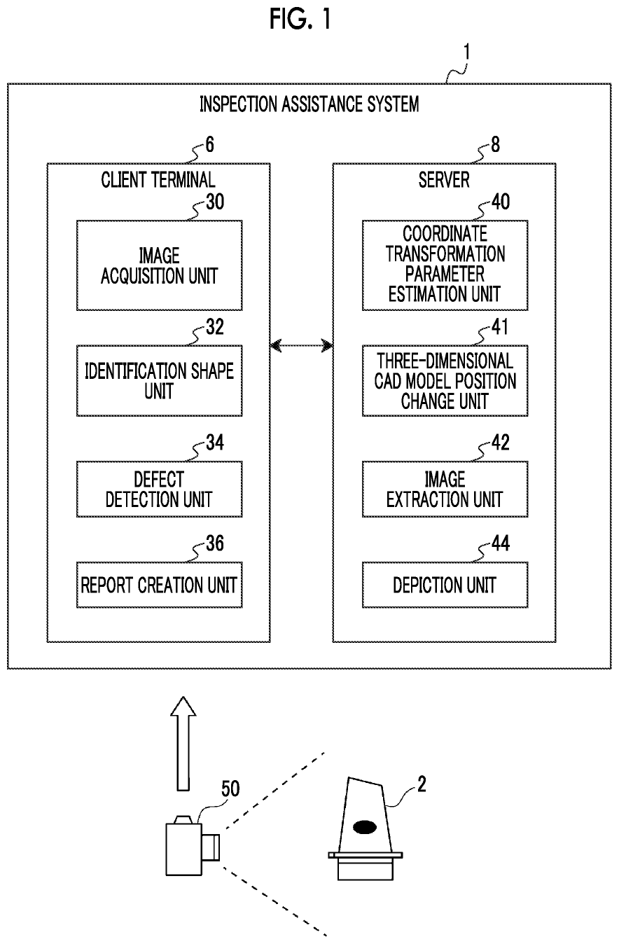

FIG. 1 is a block diagram illustrating a schematic configuration of an inspection assistance system 1 according to one embodiment. The inspection assistance system 1 is a system for supporting detection of a defect in an inspection target object 2 and creation of a report relating to inspection work when the inspection work is performed on the inspection target object 2. A user of the inspection assistance system 1 may be a worker who performs the inspection work, may be a user who uses the inspection target object 2, or may be another third party. Further, the defect detected by the inspection assistance system 1 is a defect that can be determined from appearance, and a type thereof is, for example, a crack, a dent, a scratch, a coating defect, oxidation, a thickness reduction, a stain, or the like.

The inspection target object 2 may be an entire product, may be parts constituting the product (for example, mechanical components), or the like. Further, the inspection target object 2 may be a new product, may be a repaired product, or may be an existing facility. The inspection target object 2 may be, for example, a rotor blade, a stator vane, split ring, a combustor, or the like of a gas turbine.

The inspection assistance system 1 is configured to include at least one computer device. The inspection assistance system 1 may be configured as a single device, but in FIG. 1, may be configured to include a client terminal 6 and a server 8 that are communication terminals capable of communicating with each other via a communication network 4, and the client terminal 6 and the server 8 cooperate with each other to realize functions of the inspection assistance system 1.

The communication network 4 may be a wide area network (WAN) or a local area network (LAN), and may be wireless or wired.

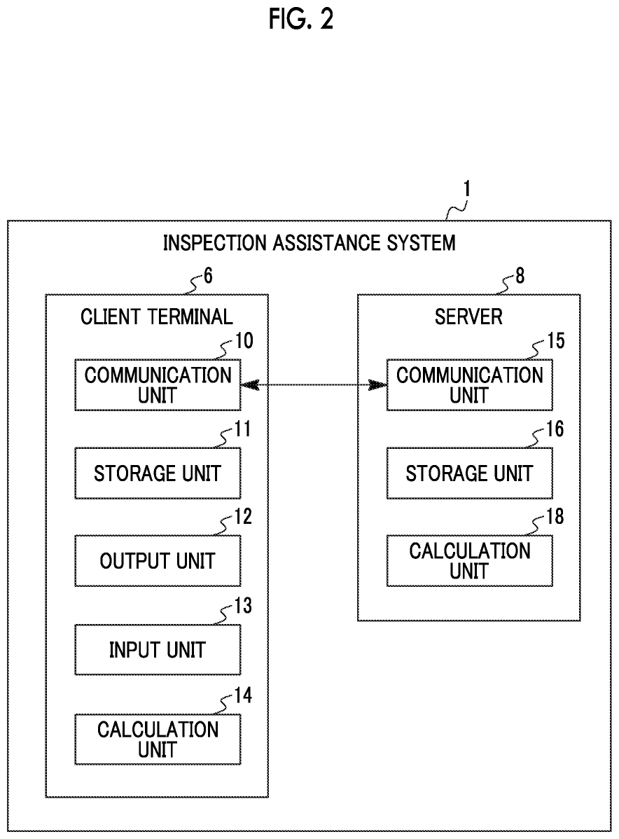

Here, FIG. 2 is a schematic diagram illustrating a hardware configuration of the client terminal 6 and the server 8 of FIG. 1. The client terminal 6 includes a communication unit 10 to communicate with the server 8, a storage unit 11 for storing various data, an output unit 12 to output various information, an input unit 13 to receive a user input, and a calculation unit 14 to perform various calculations. The server 8 includes a communication unit 15 to communicate with the client terminal 6, a storage unit 16 to store various data, and a calculation unit 18 to perform various calculations. In the client terminal 6 and the server 8, these internal configurations are connected to each other via a bus line.

The communication units 10 and 15 are communication interfaces including a network interface controller (NIC) to perform wired communication or wireless communication, and enable communication between the client terminal 6 and the server 8.

The storage units 11 and 16 are configured with a random-access memory (RAM), a read-only memory (ROM), or the like, and store programs (for example, an inspection assistance program and a trained model described later) to execute various control processing to be executed on the client terminal 6 and the server 8, respectively and data required for various control processing.

The various data include a three-dimensional CAD model of a plurality of target objects. In the present embodiment, the three-dimensional CAD model is stored in the storage unit 16 that the server 8 has. In general, the three-dimensional CAD model of the plurality of target objects requires a large storage capacity, and thus is stored in the storage unit 16 on the side of the server 8, so that it is possible to prevent the storage capacity on the side of the client terminal 6 from being constrained. In this case, since the client terminal 6 can be realized by, for example, a small terminal such as a laptop computer or a portable terminal, it is effective in improving convenience.

The plurality of target objects include the inspection target object 2 described above. The three-dimensional CAD model is three-dimensional CAD data illustrating the target object as a mesh image in a three-dimensional virtual space having actual dimensions. The mesh image can be rotated, enlarged, and reduced, and the three-dimensional CAD model is configured to be capable of extracting a two-dimensional simulated image from any viewpoint.

The storage units 11 and 16 may be configured with a single storage device or may be configured with a plurality of storage devices. Further, the storage units 11 and 16 may be external storage devices.

The output unit 12 is configured with, for example, an output device such as a display device and a speaker device. The output unit 12 is an output interface for presenting various information to the user.

The input unit 13 is an input interface for inputting information necessary for performing various processing from the outside, and is configured with, for example, an input device such as an operation button, a keyboard, a pointing device, and a microphone. Such information includes, in addition to an instruction by the user, data or the like related to a two-dimensional photographed image acquired by an imaging device as will be described later.

The calculation units 14 and 18 are configured to include a processor such as a central processing unit (CPU) and a graphics processing unit (GPU). The calculation units 14 and 18 control the operation of the entire system by executing the programs stored in the storage units 11 and 16.

Subsequently, the functional configurations of the client terminal 6 and the server 8 constituting the inspection assistance system 1 will be specifically described. As illustrated in FIG. 1, the client terminal 6 includes an image acquisition unit 30, a identification shape unit 32, a defect detection unit 34, and a report creation unit 36. The server 8 includes a coordinate transformation parameter estimation unit 40, a three-dimensional CAD model position change unit 41, an image extraction unit 42, and a depiction unit 44.

In the present embodiment, a case where these functional configurations are disposed over the client terminal 6 and the server 8 is illustrated, but these functional configurations may be disposed at any one of the client terminal 6 and the server 8. For example, the present embodiment may be realized by the client terminal 6 alone without using the server 8 by disposing the configuration illustrated on the side of the server 8 side in FIG. 1 on the client terminal 6. Further, the functional configuration included in one of the client terminal 6 or the server 8 may be appropriately disposed in the other. As described above, the layout of the functional configuration included in the inspection assistance system 1 can be appropriately modified according to the intended use.

The image acquisition unit 30 acquires a two-dimensional photographed image obtained by capturing the inspection target object 2 with an imaging device 50. The imaging device 50 is, for example, a camera compatible with visible light, and is configured to acquire a two-dimensional photographed image that is an image obtained by capturing the inspection target object 2. The acquisition of the two-dimensional photographed image by the imaging device 50 may be performed at the same place as the inspection assistance system 1, particularly at the client terminal 6 into which the two-dimensional photographed image is input, or may be performed at a different place (remote place). Data related to such a two-dimensional photographed image is acquired by being input to the input unit 13 of the client terminal 6.

The identification shape unit 32 recognizes the two-dimensional shape of the inspection target object 2 in the two-dimensional photographed image acquired by the image acquisition unit 30. The identification shape unit 32 may be configured to recognize the shape of the inspection target object 2 included in the two-dimensional photographed image by detecting a plurality of reference portions of the inspection target object 2 in the two-dimensional photographed image.

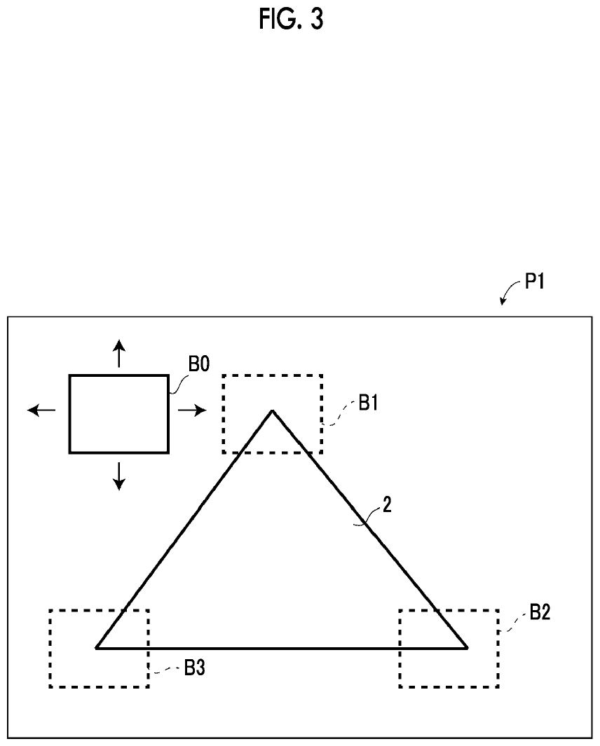

Here, FIG. 3 is a conceptual diagram for describing a method of detecting a reference portion via the identification shape unit 32 of FIG. 1. In addition, although FIG. 3 illustrates a case where the inspection target object 2 has a triangular shape in a front view, the shape thereof is not limited.

First, the identification shape unit 32 is configured to detect a characteristic portion of the inspection target object 2 as a reference portion. In one embodiment, the characteristic portion is a corner portion. The characteristic portion may be any portion useful for recognizing the shape, and may be, for example, a mark, a trademark, a keyhole, a button, or the like that serves as a mark.

In the method for detecting a reference portion in one embodiment, machine learning (for example, single shot multibox detector (SSD) technology) is used. The SSD technique is known as a technique for detecting an object in an image via deep learning. Specifically, as illustrated in FIG. 3, the identification shape unit 32 searches the inside of a two-dimensional photographed image P1 by using a default box B0, and detects a corner portion of the inspection target object 2 as a reference portion. The shape of the reference portion is recognized based on an RGB value indicating a red, green, and blue component for each pixel, a hue compared with other pixels, and brightness information.

As a result, default boxes B1, B2, and B3 corresponding to three corner portions are detected as reference portions. In addition, the identification shape unit 32 can detect the reference portion by including the brightness information in the input, although there is some brightness variation due to, for example, a portion of the two-dimensional photographed image P1 being slightly blurred. For the detection of the reference portion based on such brightness information, for example, by using an estimation model constructed by machine learning using an image in which variations in brightness are used as training data, the reference portion of the two-dimensional photographed image P1 including some brightness variations can be detected.

As described above, since the identification shape unit 32 detects the reference portion based on the RGB value, the hue, and the brightness information, it is possible to reduce detection error due to the variation in the brightness. In addition, when the shape of the reference portion is recognized by machine learning via deep learning, the work by an operator can be automated and the work time can also be shortened as compared with a case where the operator specifies the reference portion based on subjective judgement.

In another embodiment, as another method of machine learning used for detecting the reference portion, for example, a region-based convolutional neural network (R-CNN) or you only look once (YOLO) can also be used.

The defect detection unit 34 detects a defect of the inspection target object 2 included in the two-dimensional photographed image. The defect detection unit 34 may detect a defect of the inspection target object 2 by using a trained model in which machine learning is performed for a relationship between a two-dimensional photographed image of each of a plurality of target objects including the inspection target object 2 and a defect image that may occur in the plurality of target objects. For example, the defect detection unit 34 may be configured to analyze an RGB value of each pixel of a two-dimensional photographed image and to determine a defect via pattern classification of a contrast or a hue thereof.

The coordinate transformation parameter estimation unit 40 estimates a coordinate transformation parameter to transform a first coordinate system corresponding to the three-dimensional CAD model into a second coordinate system corresponding to a two-dimensional photographed image, based on the shape recognized by the identification shape unit 32 and on the three-dimensional CAD model of the inspection target object 2. The coordinate transformation parameter is a parameter for transforming each other's coordinate points in the first coordinate system and the second coordinate system, and there is a perspective-n-point problem (PNP) as one of the estimation methods. In other words, the coordinate transformation parameter is a parameter for estimating a position and a posture that defines viewpoint information of an imaging device in the first coordinate system, based on a reference portion of n points (n is any optional natural number) represented by three-dimensional coordinates in the first coordinate system corresponding to the three-dimensional CAD model handled on three-dimensional CG software, and on the reference portion thereof represented by the two-dimensional coordinates in the second coordinate system corresponding to a two-dimensional photographed image.

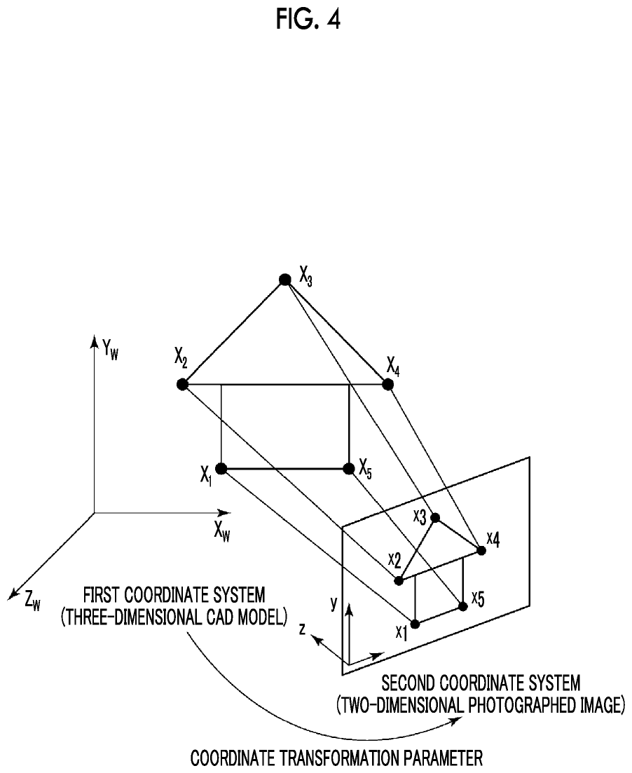

Here, FIG. 4 is a diagram conceptually illustrating a correspondence relationship between the first coordinate system and the second coordinate system based on the coordinate transformation parameter estimated by the PNP. In the PNP, coordinate transformation parameters (a translational vector, a rotation matrix, or the like) are estimated as parameters for performing transformation between the three-dimensional coordinates (X1, X2, . . . ) of n points in the first coordinate system, which is a world coordinate system corresponding to a three-dimensional CAD model handled on 3D graphic software, and the two-dimensional coordinates (x1, x2, . . . ) of n points in the second coordinate system corresponding to the viewpoint of the imaging device 50 that has captured a two-dimensional photographed image including the points thereof.

For example, in the first coordinate system and the second coordinate system, the estimation of the coordinate transformation parameter in the PNP is performed such that the reference portions corresponding to each other coincide with each other. Specifically, the coordinate transformation parameter estimation unit 40 specifies a plurality of first reference portions (a plurality of coordinate points in the second coordinate system) of the inspection target object 2 in the two-dimensional photographed image based on the shape recognized by the identification shape unit 32, by for example, automatic detection using machine learning or manual input by a user, and registers in advance a plurality of second reference portions (a plurality of coordinate points in the first coordinate system) in the three-dimensional CAD model. The registration of the second reference portion is performed by registering the second reference portion in a database or the like in advance. Such registration of the second reference portion may be performed, for example, by displaying the three-dimensional CAD model on a screen and designating the second reference portion via an operator using a cursor, a pointer, or the like on the screen. Then, the coordinate transformation parameter is estimated such that the first reference portion and the second reference portion coincide with each other.

The coordinate transformation parameter includes an external parameter of the imaging device 50. The external parameter is a parameter necessary for defining the position and the direction (degree of freedom: 6) of the imaging device 50 in the first coordinate system. That is, it is a parameter for reproducing the same place as an imaging position of the two-dimensional photographed image in the first coordinate system instead of a relative position, and is represented by, for example, a translational vector or a rotation matrix.

Further, the coordinate transformation parameter may include an internal parameter of the imaging device 50. The internal parameter of the imaging device 50 is a parameter relating to a main body (lens) of the imaging device 50 and is, for example, a focal distance f or an optical center. The optical center corresponds to an origin of the second coordinate system, is a parameter unique to the lens, and is represented as two-dimensional coordinates (Cu, Cv). In this case, a relational expression between the three-dimensional coordinates (Xw, Yw, Zw) of feature points in the first coordinate system corresponding to the three-dimensional CAD model, and the two-dimensional coordinates (u, v) of feature points in the second coordinate system corresponding to the two-dimensional photographed image are expressed as follows.

$$[ \begin{matrix}u \\ v \\ 1\end{matrix} ] \sim [ \begin{matrix}f & 0 & {C}_{u} \\ 0 & f & {C}_{v} \\ 0 & 0 & 1\end{matrix} ] [ \begin{matrix}{R}_{11} & {R}_{12} & {R}_{13} & {T}_{1} \\ {R}_{21} & {R}_{22} & {R}_{23} & {T}_{2} \\ {R}_{31} & {R}_{32} & {R}_{33} & {T}_{3}\end{matrix} ] [ \begin{matrix}{X}_{w} \\ {Y}_{w} \\ {Z}_{w} \\ 1\end{matrix} ]$$

Returning to FIG. 1, the three-dimensional CAD model position change unit 41 modifies the position and the direction of the viewpoint information of the three-dimensional CAD model of the inspection target object 2 by using the coordinate transformation parameter estimated by the coordinate transformation parameter estimation unit 40. Accordingly, the viewpoint information of the three-dimensional CAD model indicated by the viewpoint from the camera at a specific position and direction on the rendering software of the three-dimensional CAD model is modified to correspond to the position and direction corresponding to the viewpoint of the imaging device 50 that has captured the two-dimensional photographed image.

The image extraction unit 42 refers to a three-dimensional CAD model whose viewpoint information has been modified by the three-dimensional CAD model position change unit 41 based on the recognition result by the identification shape unit 32, and from the three-dimensional CAD model, extracts a two-dimensional simulated image corresponding to the two-dimensional photographed image.

The depiction unit 44 adjusts the defect image illustrating the defect detected by the defect detection unit 34 to fit the two-dimensional simulated image, and depicts the adjusted defect image on the three-dimensional CAD model. This adjustment may be performed before the depiction or at the time of the depiction, or may be performed on a defect image that has already been depicted after the depiction has been done once. The three-dimensional CAD model in a state in which the defect image is depicted may be displayed on the display device of the output unit 12.

For example, the depiction unit 44 uses a transformation method such as a geometric transformation (plane transformation), for example, an affine transformation, to use a reference portion (a plurality of coordinate points) of a target image as an input value, and performs projection onto the three-dimensional CAD model by transforming the two-dimensional photographed image into the coordinate system of the two-dimensional simulated image. At this time, since the viewpoint information of the three-dimensional CAD model is modified as described above, the depiction unit 44 defines the defect along the transformed coordinates, projects the defect, and thus performs rendering on the three-dimensional CAD model.

For example, the depiction unit 44 may compare the lengths of the sides determined from a positional relationship of the plurality of reference portions between the two-dimensional photographed image and the two-dimensional simulated image, and may enlarge or reduce the defect image based on their similarity ratios. The depiction unit 44 may compare the positional relationships of the plurality of reference portions between the two-dimensional photographed image and the two-dimensional simulated image, and may perform adjustment of an aspect ratio, parallel movement, linear transformation, or the like of the defect image.

In the present embodiment, a case where the depiction unit 44 transforms the defect image is illustrated, but, as another example of the transformation, an affine transformation, a projection transformation, a similarity transformation, an inversion transformation, a fluoroscopic transformation, or the like may be used.

The report creation unit 36 derives the three-dimensional position and dimension of the defect in the inspection target object 2 from the dimensional data of the three-dimensional CAD model, and creates a report including the derivation result of the position and the dimension. The created report may be stored in the storage unit 11 or may be transmitted to another device (for example, a server device that manages the report).

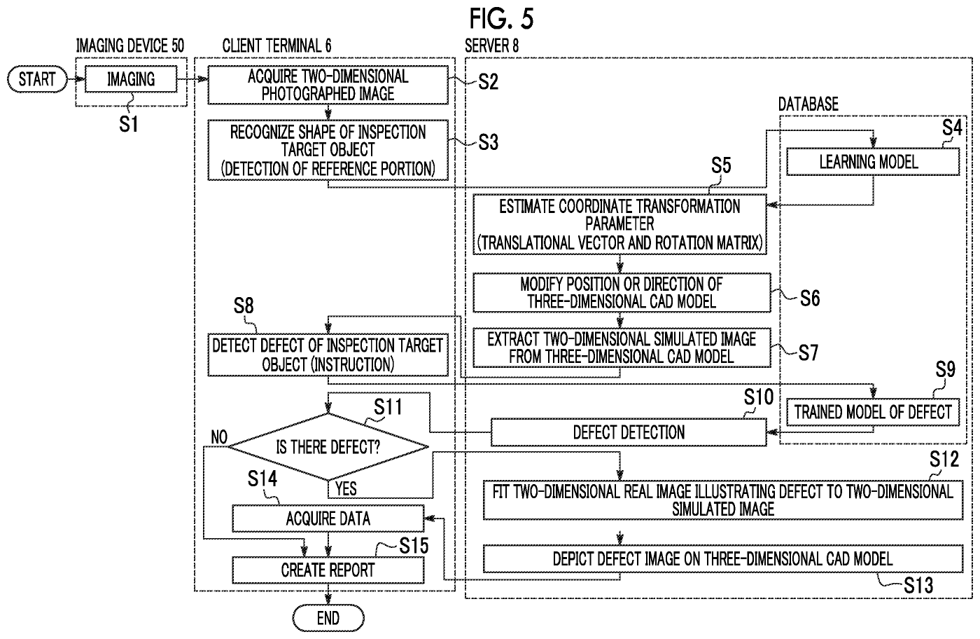

Subsequently, an inspection assistance method implemented by the inspection assistance system 1 having the above configuration will be described. FIG. 5 is a flowchart illustrating an inspection assistance method according to one embodiment.

First, as a pre-stage in which the inspection assistance method is implemented, the inspection target object 2 is captured using the imaging device 50 (step S1). In step S1, imaging can be performed on the inspection target object 2 from any optional position and direction, and the two-dimensional photographed image obtained by the imaging device 50 is input to the client terminal 6 as data.

In the client terminal 6, the image acquisition unit 30 acquires a two-dimensional photographed image as the data inputted from the imaging device 50 (step S2). Subsequently, in the client terminal 6, the identification shape unit 32 detects a reference portion of the inspection target object 2 in the two-dimensional photographed image acquired in step S2 to recognize the shape of the inspection target object 2 (step S3).

Subsequently, the coordinate transformation parameter estimation unit 40 accesses a learning model relating to the reference portion detected when the shape is recognized in step S3 (step S4), and estimates the coordinate transformation parameters (step S5). The method for estimating the coordinate transformation parameter is specifically performed by, for example, the PNP as described above.

Subsequently, the three-dimensional CAD model position change unit 41 modifies at least one of the position or the direction of the three-dimensional CAD model by using the coordinate transformation parameters (for example, a translational vector, a rotation matrix, or the like) estimated in step S5 (step S6).

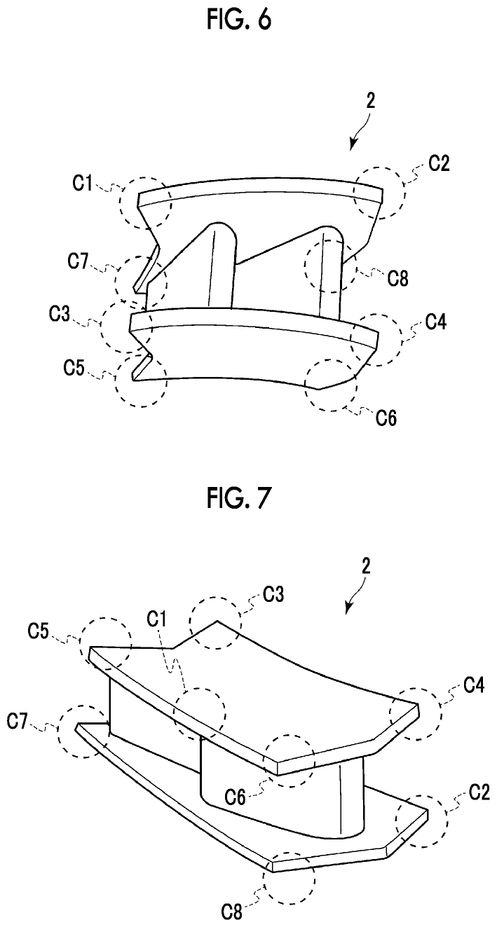

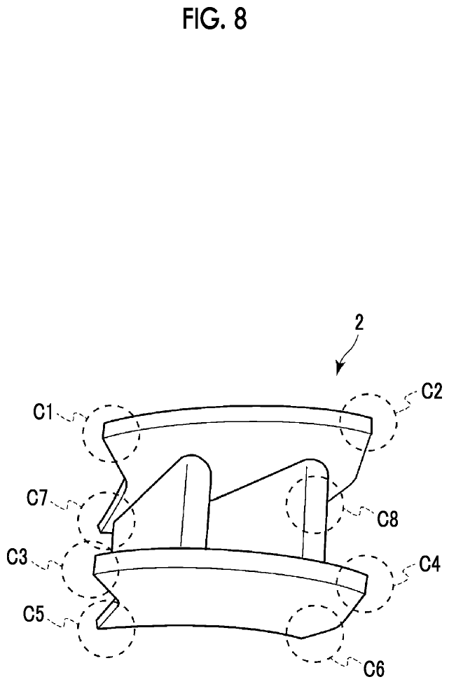

Here, the processing by the three-dimensional CAD model position change unit 41 will be specifically described with reference to FIGS. 6 to 8. FIG. 6 is an example of a two-dimensional photographed image captured by the imaging device 50, FIG. 7 is a schematic diagram illustrating a default position of a three-dimensional CAD model, and FIG. 8 is a schematic diagram illustrating a posture of the three-dimensional CAD model of FIG. 7 after at least one of a position or direction thereof is modified by the three-dimensional CAD model position change unit 41.

As illustrated in FIG. 6, in the two-dimensional photographed image captured by the imaging device 50, reference portions C1 to C7 among a plurality of reference portions C1 to C8 of the inspection target object 2 are reflected. However, in the default position of the three-dimensional CAD model illustrated in FIG. 7, only a portion of a plurality of reference portions included in the inspection target object 2 illustrated in FIG. 6 can be confirmed (specifically, in FIG. 7, the reference portions C2 to C8 common to FIG. 6 are seen, but the reference portion C1 in FIG. 6 is not seen). In the three-dimensional CAD model having such a default position, as illustrated in FIG. 8, at least one of a position or a direction of the three-dimensional CAD model having a default position illustrated in FIG. 6 is modified by the coordinate transformation parameter to obtain the posture corresponding to the two-dimensional photographed image illustrated in FIG. 6, so that all the reference portions C1 to C7 are included.

Subsequently, the image extraction unit 42 of the server 8 extracts the two-dimensional simulated image including portions corresponding to a plurality of reference portions of the inspection target object 2 detected from the two-dimensional photographed image, from the three-dimensional CAD model whose viewpoint information is modified by the three-dimensional CAD model position change unit 41 (step S7). In step S7, for example, a two-dimensional simulated image may be extracted by displaying a three-dimensional CAD model of which the viewpoint information has been modified on a screen and acquiring a screenshot of the screen. In this case, the acquisition of the screenshot may be performed by actually displaying the three-dimensional CAD model of which the viewpoint information has been modified on the screen, or may be performed computationally without displaying the three-dimensional CAD model on the screen. A rendered or trained model may be used for this extraction.

Subsequently, the defect detection unit 34 of the client terminal 6 issues a defect detection instruction of the inspection target object 2 to the server 8 based on the two-dimensional photographed image acquired in step S2 (step S8). The server 8 that has received the detection instruction accesses the learning model for defect detection prepared in advance (step S9), and executes defect detection by using the learning model (step S10).

The client terminal 6 acquires the detection result of step S10 from the server 8 and determines whether or not the inspection target object 2 has a defect based on the detection result (step S11). When it is determined that the inspection target object 2 has no defect (step S11: NO), steps S12 to S14 are skipped, and the report creation unit 36 creates a report indicating that there is no defect (step S15).

Meanwhile, when it is determined that the inspection target object 2 has no defect (step S11: NO), the depiction unit 44 of the server 8 performs fitting such that the two-dimensional photographed image (that is, defect image) illustrating the defect detected in the step S10 fits the two-dimensional simulated image (step S12), and depicts the adjusted defect image on the three-dimensional CAD model (step S13). Then, the client terminal 6 acquires data (for example, dimensional data) relating to the three-dimensional CAD model in which the defect image is depicted (for example, dimensional data) (step S14), and the report creation unit 36 derives the three-dimensional position and dimension of the defect in the inspection target object 2 from the data and creates a report including the derivation result (step S15).

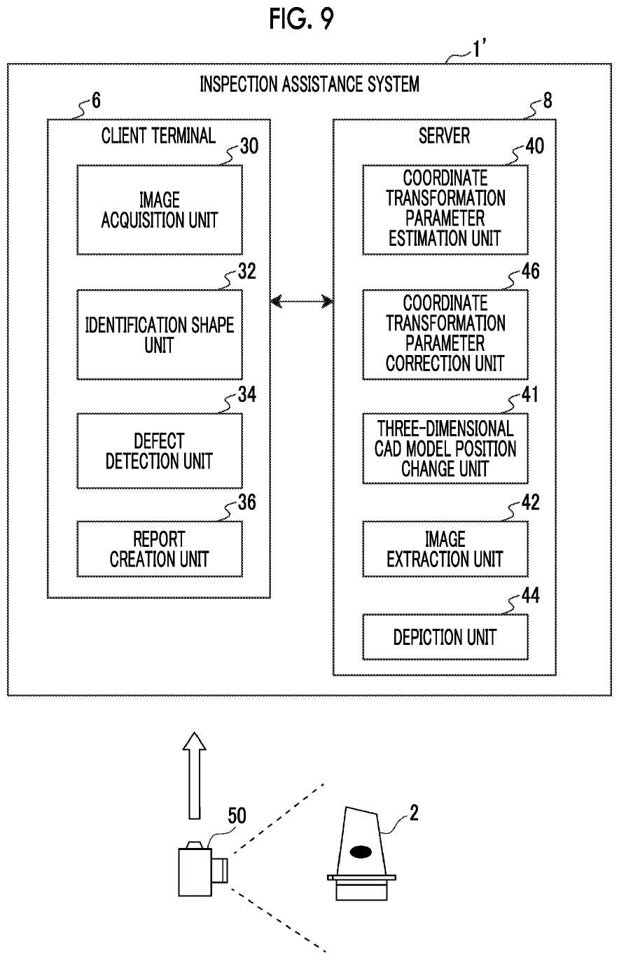

FIG. 9 is a block diagram illustrating a schematic configuration of an inspection assistance system 1′ according to another embodiment. The inspection assistance system 1′ further includes a coordinate transformation parameter correction unit 46 as compared with the above-described embodiment. The coordinate transformation parameter correction unit 46 corrects the coordinate transformation parameter estimated by the coordinate transformation parameter estimation unit 40 through noise removal using machine learning.

In the coordinate transformation parameter estimation unit 40, the coordinate transformation parameters are estimated such that the reference portion specified in the two-dimensional photographed image and the reference portion specified in the three-dimensional CAD model coincide with each other as described above. Here, the detection of each reference portion with respect to the coordinate transformation parameter estimation unit 40 is performed, for example, by measurement through image analysis in the server 8, manual designation by an operator, or machine learning using a machine learning model. Therefore, there may be an error in the estimated coordinate transformation parameter based on a measurement error in the image analysis, a human error at the time of manual input by the operator, or uncertainty in the machine learning model. In the present embodiment, the coordinate transformation parameter correction unit 46 is provided such that the coordinate transformation parameter is corrected to reduce such an error. The correction of the coordinate transformation parameter by the coordinate transformation parameter correction unit 46 can be performed, for example, by noise removal using machine learning.

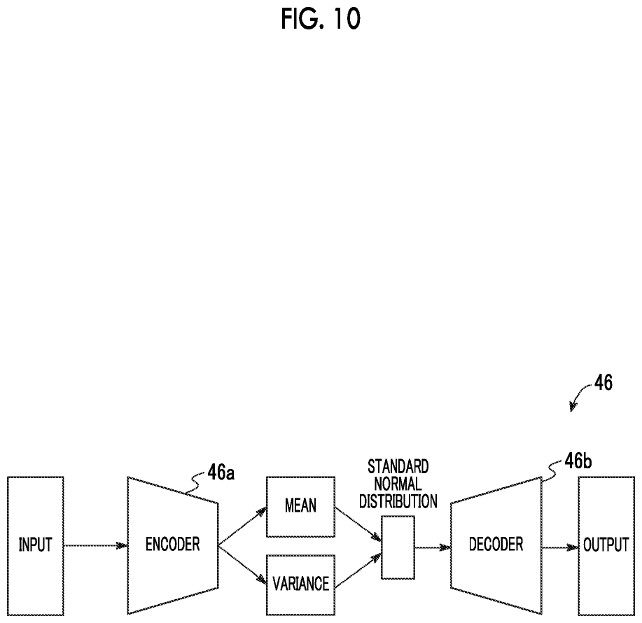

FIG. 10 is a schematic configuration diagram of the coordinate transformation parameter correction unit 46 of FIG. 9, which is configured as a Variational Autoencoder. In FIG. 10, the coordinate transformation parameter correction unit 46 includes an encoder 46a and a decoder 46b, which are a type of a neural network. A coordinate transformation parameter is given to the encoder 46a as an input to perform dimensional compression. For the output from the encoder, the mean and the variance are specified, and the distribution defined from these is corrected to be a standard normal distribution. Then, the correction result is restored by the decoder 46b and becomes the corrected coordinate transformation parameter having the original dimension. In the coordinate transformation parameter correction unit 46, an abnormality included in the coordinate transformation parameter that is inputted and uncorrected is not reproduced, and a corrected normal value is outputted.

In addition, in the above-described embodiment, the coordinate transformation parameter correction unit 46 using the Variational Autoencoders (VAEs) is exemplified, but other examples may include generative adversarial networks (GAN), principal component analysis, k-means clustering, vector quantization (VQ), or the like.

As described above, the inspection assistance system 1′ provides the coordinate transformation parameter correction unit 46, so that the error of the coordinate transformation parameter can be reduced based on a measurement error in image analysis, a human error at the time of manual input by the operator, or uncertainty in the machine learning model. As a result, the defect image can be accurately depicted with respect to the three-dimensional CAD model.

As described above, since the shape of the inspection target object included in the two-dimensional photographed image used for estimating the coordinate transformation parameter is recognized by, for example, image analysis or manual input by a worker, there is some degree of error accompanying these. According to the aspect above, by correcting the estimated coordinate transformation parameter through noise removal using machine learning, an influence of such an error is reduced, and accuracy of the coordinate transformation using the coordinate transformation parameter can be effectively improved.

As described above, according to each of the above-described embodiments, based on the shape of the inspection target object included in the two-dimensional photographed image and on the three-dimensional CAD model of the inspection target object, a coordinate transformation parameter is estimated to transform the first coordinate system corresponding to the three-dimensional CAD model into the second coordinate system corresponding to the viewpoint of the imaging device that has captured the two-dimensional photographed image. Using such a coordinate transformation parameter, the position and the direction of the viewpoint information of the three-dimensional CAD model are modified to correspond to the inspection target object included in the two-dimensional photographed image. By modifying the position and the direction of the three-dimensional CAD model to correspond to the two-dimensional photographed image by using the coordinate transformation parameter in this way, it is possible to suppress a deviation between the positions and the directions of the two without requiring an operator's operation. Then, by depicting the defect image included in the two-dimensional photographed image on the three-dimensional CAD model whose position and direction are modified in this way, it is possible to accurately measure the defect on the three-dimensional CAD model.

In addition, it is possible to appropriately replace the components in the embodiment described above with well-known components within the scope which does not depart from the gist of the present disclosure, and the embodiments described above may be combined appropriately.

The contents described in each embodiment are understood as follows, for example.

(1) An inspection assistance system according to one aspect includes
a identification shape unit to recognize a shape of an inspection target object included in a two-dimensional photographed image based on the two-dimensional photographed image obtained by capturing the inspection target object with an imaging device,
a defect detection unit to detect a defect of the inspection target object included in the two-dimensional photographed image,
a coordinate transformation parameter estimation unit to estimate a coordinate transformation parameter to transform a first coordinate system corresponding to the three-dimensional CAD model into a second coordinate system corresponding to a viewpoint of the imaging device that has captured the two-dimensional photographed image, based on the shape recognized by the identification shape unit and on a three-dimensional CAD model of the inspection target object,
a three-dimensional CAD model position change unit to modify a position and a direction of viewpoint information of the three-dimensional CAD model of the inspection target object by using the coordinate transformation parameter,
a two-dimensional simulated image extraction unit to extract a two-dimensional simulated image corresponding to the two-dimensional photographed image from the three-dimensional CAD model after the viewpoint information is modified, and
a depiction unit to depict a defect image on the three-dimensional CAD model by fitting the two-dimensional photographed image including the defect image illustrating the defect detected by the defect detection unit to the two-dimensional simulated image.

According to the aspect (1) above, based on the shape of the inspection target object included in the two-dimensional photographed image and on the three-dimensional CAD model of the inspection target object, a coordinate transformation parameter is estimated to transform the first coordinate system corresponding to the three-dimensional CAD model into the second coordinate system corresponding to the viewpoint of the imaging device that has captured the two-dimensional photographed image. This coordinate transformation parameter includes, for example, a translational vector and a rotation matrix, and is a parameter for transforming the first coordinate system into the second coordinate system that is a two-dimensional coordinate system. In other words, the coordinate transformation parameter is a parameter for estimating a position and a posture that defines viewpoint information of an imaging device in the first coordinate system, based on a reference portion of n points (n is any optional natural number) represented by three-dimensional coordinates in the first coordinate system corresponding to the three-dimensional CAD model handled on three-dimensional CG software, and on the reference portion thereof represented by the two-dimensional coordinates in the second coordinate system corresponding to a two-dimensional photographed image. Using such a coordinate transformation parameter, the position and/or direction of the viewpoint information of the three-dimensional CAD model is modified to correspond to the inspection target object included in the two-dimensional photographed image. By modifying the position and the direction of the viewpoint information of the three-dimensional CAD model to correspond to the two-dimensional photographed image by using the coordinate transformation parameter in this way, it is possible to suppress a deviation between the positions and the directions of the two without requiring an operator's operation. Then, by depicting the defect image included in the two-dimensional photographed image on the three-dimensional CAD model whose position and direction of the viewpoint information are modified in this way, it is possible to accurately measure the defect on the three-dimensional CAD model.

(2) In another aspect, in the aspect of the above (1),
the coordinate transformation parameter estimation unit specifies in advance a plurality of first reference portions of the inspection target object in the two-dimensional photographed image based on the shape recognized by the identification shape unit, and estimates the coordinate transformation parameter such that a plurality of second reference portions registered in advance in the three-dimensional CAD model coincide with the plurality of first reference portions.

According to the aspect (2) above, the coordinate transformation parameter is estimated such that the first reference portion specified in advance for the inspection target object included in the two-dimensional photographed image and the second reference portion registered in advance in the three-dimensional CAD model coincide with each other. By using the coordinate transformation parameters estimated in this way, the position and the posture of the viewpoint information of the three-dimensional CAD model can be fitted to the position and the posture of the inspection target object included in the two-dimensional photographed image, so that it is possible to effectively suppress the occurrence of deviation in the position and the direction of the defect depicted in the three-dimensional CAD model.

(3) In another aspect, in the aspect of the above (1) or (2),
the coordinate transformation parameter includes an external parameter for defining a position and a posture of the imaging device in the first coordinate system.

According to the aspect (3) above, by including the external parameter in the coordinate transformation parameter, the first coordinate system corresponding to the three-dimensional CAD model can be suitably transformed into the second coordinate system corresponding to the two-dimensional photographed image.

(4) In another aspect, in the aspect of the above (3),
the coordinate transformation parameter further includes an internal parameter relating to the imaging device.

According to the aspect (4) above, the coordinate transformation parameters include, for example, internal parameters such as a focal distance and an optical center, which are parameters unique to the imaging device. As a result, although a two-dimensional photographed image is acquired using a different imaging device, the first coordinate system corresponding to the three-dimensional CAD model can be suitably transformed into the second coordinate system corresponding to the two-dimensional photographed image by using the coordinate transformation parameters that take into consideration the characteristics (differences in specifications, individual differences, or the like) unique to each imaging device.

(5) In another aspect, in any one of the above (1) to (4),

the depiction unit adjusts a position and a dimension of the depicted defect image by performing plane transformation of the two-dimensional photographed image including the defect image based on a result of comparing the two-dimensional photographed image with the two-dimensional simulated image.

According to the aspect (5) above, the two-dimensional photographed image and the two-dimensional simulated image are compared, and the position and the dimension of the defect image are adjusted based on the difference in the positional relationship, the shapes, the dimensions, or the like thereof. In this case, for example, as compared with a case where lines illustrating contours of the inspection target object are compared with each other to adjust the position and the dimension of the defect image, it is possible to simplify processing or to improve adjustment accuracy.

(6) In another aspect, in any one of the above (1) to (5),
a report creation unit that derives a three-dimensional position and dimension of the defect in the inspection target object based on the defect image projected onto the three-dimensional CAD model from dimensional data of the three-dimensional CAD model, and that creates a report including a derivation result of the position and the dimension is further included.

According to the aspect (6) above, since the report including the three-dimensional position and dimension of the defect is created, a work load for creating the report is reduced. In addition, by collecting information on the position and the dimension of the defect with respect to the same three-dimensional CAD model in a plurality of cases, statistics (for example, when the defect is a dent, the position at which the dent is likely to be identified can be specified from the statistical data) can also be obtained.

(7) In another aspect, in any one of the above (1) to (6),
a coordinate transformation parameter correction unit to correct the coordinate transformation parameter through noise removal using machine learning is further included.

As described above, since the shape of the inspection target object included in the two-dimensional photographed image used for estimating the coordinate transformation parameter is recognized by, for example, image analysis or manual input by a worker, there is some degree of error accompanying these. According to the aspect (7) above, by correcting the estimated coordinate transformation parameter through noise removal using machine learning, an influence of such an error is reduced, and accuracy of the coordinate transformation using the coordinate transformation parameter can be effectively improved.

(8) An inspection assistance method according to one aspect includes
a step of recognizing a shape of an inspection target object included in a two-dimensional photographed image based on the two-dimensional photographed image obtained by capturing the inspection target object with an imaging device,
a step of detecting a defect of the inspection target object included in the two-dimensional photographed image,
a step of estimating a coordinate transformation parameter to transform a first coordinate system corresponding to the three-dimensional CAD model into a second coordinate system corresponding to a viewpoint of the imaging device that has captured the two-dimensional photographed image, based on the shape and a three-dimensional CAD model of the inspection target object,
a step of modifying a position and a direction of viewpoint information of the three-dimensional CAD model of the inspection target object by using the coordinate transformation parameter,
a step of extracting a two-dimensional simulated image corresponding to the two-dimensional photographed image from the three-dimensional CAD model after the viewpoint information is modified, and
a step of depicting a defect image on the three-dimensional CAD model by fitting the two-dimensional photographed image including the defect image illustrating the defect to the two-dimensional simulated image.

According to the aspect (8) above, based on the shape of the inspection target object included in the two-dimensional photographed image and on the three-dimensional CAD model of the inspection target object, a coordinate transformation parameter is estimated to transform the first coordinate system corresponding to the three-dimensional CAD model into the second coordinate system corresponding to the viewpoint of the imaging device that has captured the two-dimensional photographed image. This coordinate transformation parameter includes, for example, a translational vector and a rotation matrix, and is a parameter for transforming the first coordinate system into the second coordinate system that is a two-dimensional coordinate system. In other words, the coordinate transformation parameter is a parameter for estimating a position and a posture that defines viewpoint information of an imaging device in the first coordinate system, based on a reference portion of n points (n is any optional natural number) represented by three-dimensional coordinates in the first coordinate system corresponding to the three-dimensional CAD model handled on three-dimensional CG software, and on the reference portion thereof represented by the two-dimensional coordinates in the second coordinate system corresponding to a two-dimensional photographed image. Using such a coordinate transformation parameter, at least one of the position or the direction of the viewpoint information of the three-dimensional CAD model is modified to correspond to the inspection target object included in the two-dimensional photographed image. By modifying the position and the direction of the viewpoint information of the three-dimensional CAD model to correspond to the two-dimensional photographed image by using the coordinate transformation parameter in this way, it is possible to suppress a deviation between the positions and the directions of the two without requiring an operator's operation. Then, by depicting the defect image included in the two-dimensional photographed image on the three-dimensional CAD model whose position and direction of the viewpoint information are modified in this way, it is possible to accurately measure the defect on the three-dimensional CAD model.

(9) An inspection assistance computer-readable recording medium storing a program according to one aspect causes
a computer to execute
a step of recognizing a shape of an inspection target object included in a two-dimensional photographed image based on the two-dimensional photographed image obtained by capturing the inspection target object with an imaging device,
a step of detecting a defect of the inspection target object included in the two-dimensional photographed image,
a step of estimating a coordinate transformation parameter to transform a first coordinate system corresponding to the three-dimensional CAD model into a second coordinate system corresponding to a viewpoint of the imaging device that has captured the two-dimensional photographed image, based on the shape and a three-dimensional CAD model of the inspection target object,
a step of modifying at least one of a position and a direction of viewpoint information of the three-dimensional CAD model of the inspection target object by using the coordinate transformation parameter,
a step of extracting a two-dimensional simulated image corresponding to the two-dimensional photographed image from the three-dimensional CAD model after the viewpoint information is modified, and
a step of depicting a defect image on the three-dimensional CAD model by fitting the two-dimensional photographed image including the defect image illustrating the defect to the two-dimensional simulated image.

According to the aspect (9) above, based on the shape of the inspection target object included in the two-dimensional photographed image and on the three-dimensional CAD model of the inspection target object, a coordinate transformation parameter is estimated to transform the first coordinate system corresponding to the three-dimensional CAD model into the second coordinate system corresponding to the viewpoint of the imaging device that has captured the two-dimensional photographed image. This coordinate transformation parameter includes, for example, a translational vector and a rotation matrix, and is a parameter for transforming the first coordinate system into the second coordinate system that is a two-dimensional coordinate system. In other words, the coordinate transformation parameter is a parameter for estimating a position and a posture that defines viewpoint information of an imaging device in the first coordinate system, based on a reference portion of n points (n is any optional natural number) represented by three-dimensional coordinates in the first coordinate system corresponding to the three-dimensional CAD model handled on three-dimensional CG software, and on the reference portion thereof represented by the two-dimensional coordinates in the second coordinate system corresponding to a two-dimensional photographed image. Using such a coordinate transformation parameter, the position and the direction of the viewpoint information of the three-dimensional CAD model are modified to correspond to the inspection target object included in the two-dimensional photographed image. By modifying the position and the direction of the viewpoint information of the three-dimensional CAD model to correspond to the two-dimensional photographed image by using the coordinate transformation parameter in this way, it is possible to suppress a deviation between the positions and the directions of the two without requiring an operator's operation. Then, by depicting the defect image included in the two-dimensional photographed image on the three-dimensional CAD model whose position and direction of the viewpoint information are modified in this way, it is possible to accurately measure the defect on the three-dimensional CAD model.

### REFERENCE SIGNS LIST

1: inspection assistance system
2: inspection target object
4: communication network
6: client terminal
8: server
10: communication unit
11: storage unit
12: output unit
13: input unit
14: calculation unit
15: communication unit
16: storage unit
18: calculation unit
30: image acquisition unit
32: identification shape unit
34: defect detection unit
36: report creation unit
40: coordinate transformation parameter estimation unit
41: three-dimensional CAD model position change unit
42: image extraction unit
44: depiction unit
50: imaging device

1. An inspection assistance system comprising:
a identification shape unit that recognizes a shape of an inspection target object included in a two-dimensional photographed image based on the two-dimensional photographed image obtained by capturing the inspection target object with an imaging device;
a defect detection unit to detect a defect of the inspection target object included in the two-dimensional photographed image;
a coordinate transformation parameter estimation unit to estimate a coordinate transformation parameter to transform a first coordinate system corresponding to the three-dimensional CAD model into a second coordinate system corresponding to a viewpoint of the imaging device that has captured the two-dimensional photographed image based on the shape recognized by the identification shape unit and on a three-dimensional CAD model of the inspection target object;
a three-dimensional CAD model position change unit to modify a position and a direction of viewpoint information of the three-dimensional CAD model of the inspection target object by using the coordinate transformation parameter;
a two-dimensional simulated image extraction unit to extract a two-dimensional simulated image corresponding to the two-dimensional photographed image from the three-dimensional CAD model after the viewpoint information is modified; and
a depiction unit to depict a defect image illustrating the defect detected by the defect detection unit on the three-dimensional CAD model by fitting the two-dimensional photographed image including the defect image to the two-dimensional simulated image.

2. The inspection assistance system according to claim 1, wherein
the coordinate transformation parameter estimation unit specifies in advance a plurality of first reference portions of the inspection target object in the two-dimensional photographed image based on the shape recognized by the identification shape unit, and estimates the coordinate transformation parameter such that a plurality of second reference portions registered in advance in the three-dimensional CAD model coincide with the plurality of first reference portions.

3. The inspection assistance system according to claim 1, wherein
the coordinate transformation parameter includes an external parameter for defining a position and a posture of the imaging device in the first coordinate system.

4. The inspection assistance system according to claim 3, wherein
the coordinate transformation parameter further includes an internal parameter relating to the imaging device.

5. The inspection assistance system according to claim 1, wherein
the depiction unit adjusts a position and a dimension of the depicted defect image by performing plane transformation of the two-dimensional photographed image including the defect image based on a result of comparing the two-dimensional photographed image with the two-dimensional simulated image.

6. The inspection assistance system according to claim 1, further comprising:
a report creation unit that derives a three-dimensional position and dimension of the defect in the inspection target object based on the defect image projected onto the three-dimensional CAD model from dimensional data of the three-dimensional CAD model, and that creates a report including a derivation result of the position and the dimension.

7. The inspection assistance system according to claim 1, further comprising:
a coordinate transformation parameter correction unit to correct the coordinate transformation parameter through noise removal using machine learning.

8. An inspection assistance method comprising:
a step of recognizing a shape of an inspection target object included in a two-dimensional photographed image based on the two-dimensional photographed image obtained by capturing the inspection target object with an imaging device;
a step of detecting a defect of the inspection target object included in the two-dimensional photographed image;
a step of estimating a coordinate transformation parameter to transform a first coordinate system corresponding to the three-dimensional CAD model into a second coordinate system corresponding to a viewpoint of the imaging device that has captured the two-dimensional photographed image, based on the shape and a three-dimensional CAD model of the inspection target object;
a step of modifying a position and a direction of viewpoint information of the three-dimensional CAD model of the inspection target object by using the coordinate transformation parameter;
a step of extracting a two-dimensional simulated image corresponding to the two-dimensional photographed image from the three-dimensional CAD model after the viewpoint information is modified; and
a step of depicting a defect image on the three-dimensional CAD model by fitting the two-dimensional photographed image including the defect image illustrating the defect to the two-dimensional simulated image.

9. A computer-readable storage medium that stores an inspection assistance computer-readable recording medium storing a program that causes a computer to execute:
a step of recognizing a shape of an inspection target object included in a two-dimensional photographed image based on the two-dimensional photographed image obtained by capturing the inspection target object with an imaging device;
a step of detecting a defect of the inspection target object included in the two-dimensional photographed image;
a step of estimating a coordinate transformation parameter to transform a first coordinate system corresponding to the three-dimensional CAD model into a second coordinate system corresponding to a viewpoint of the imaging device that has captured the two-dimensional photographed image, based on the shape and a three-dimensional CAD model of the inspection target object;
a step of modifying a position and a direction of viewpoint information of the three-dimensional CAD model of the inspection target object by using the coordinate transformation parameter;
a step of extracting a two-dimensional simulated image corresponding to the two-dimensional photographed image from the three-dimensional CAD model after the viewpoint information is modified; and
a step of depicting a defect image on the three-dimensional CAD model by fitting the two-dimensional photographed image including the defect image illustrating the defect to the two-dimensional simulated image.
